(19) United States
(12) Patent Application Publication
(10) Pub. No.: US 2004/0171231 A1
(43) Pub. Date: Sep. 2, 2004

(54) Bonding system and semiconductor substrate manufacturing method

(76) Inventors: Kazutaka Yanagita, Kanagawa (JP); Kenji Yamagata, Kanagawa (JP)

Correspondence Address: FITZPATRICK CELLA HARPER & SCINTO, 30 ROCKEFELLER PLAZA, NEW YORK, NY, 10112, US

(21) Appl. No.: 10/787,195

(22) Filed: Feb. 27, 2004

(30) Foreign Application Priority Data
Feb. 28, 2003 (JP) 2003-054137
Feb. 28, 2003 (JP) 2003-054138

(51) Int. Cl. H01L 21/30

(52) U.S. Cl. 438/455

(57) ABSTRACT

A unit which overlays first and second substrates, after the surfaces of the first and second substrates are cleaned and/or activated, is accommodated in a chamber, and the interior of the chamber is isolated from an outer space. In the chamber isolated from the outer space, the state of the surfaces of the first and second substrates is measured. The surfaces of the first and second substrates are cleaned on the basis of the measurement result. After that, the first and second substrates are overlaid.

### FIELD OF THE INVENTION

The present invention relates to a bonding system for bonding substrates, and a semiconductor substrate manufacturing method.

### BACKGROUND OF THE INVENTION

In the semiconductor manufacturing process, a technique for fabricating an SOI substrate by using a bonding technique is known (see Japanese Patent Laid-Open No. 5-21338). This technique employs a wafer direct bonding technique for bonding a silicon epitaxial layer grown on porous silicon to an amorphous substrate or single-crystal silicon substrate through an oxide film. When bonding substrates, generally, a preprocess such as cleaning and activation of the substrates surface are performed.

When the preprocess is performed either as a batch process or single-wafer process, while the substrates are transported to a bonding unit, unnecessary moisture or particles such as organic substances undesirably attach to the surfaces to be bonded. This degrades the bonding strength of the substrates.

Also, for example, particles may be generated unpredictably by other units, an organic substance atmosphere may flow from an organic solvent, particles may be generated unpredictably by the operator, or an organic substance atmosphere may flow from an organic solvent attaching to the operator or the like, to contaminate the bonding surfaces of the substrates. The surface state of the bonding surface accordingly differs from one substrate to another.

Therefore, the bonding strength of the bonded substrate stack degrades, and the yield decreases.

### SUMMARY OF THE INVENTION

The present invention has been made in view of the above problems, and has as its object to improve the quality of a bonded substrate stack.

According to the first aspect of the present invention, there is provided a bonding system comprising a processing unit which processes surfaces of first and second substrates, an operation unit which overlays the first and second substrates processed by the processing unit, and a chamber which accommodates and isolates from an outer space the processing unit and operation unit, wherein a process for the first and second substrates by the processing unit includes a process of cleaning and/or activating the surfaces of the first and second substrates.

According to the second aspect of the present invention, there is provided a bonding system comprising an operation unit which overlays first and second substrates, a chamber which accommodates the operation unit and isolates the operation unit from an outer space, and a humidity maintaining unit which maintains a humidity in the chamber to a substantially constant level.

According to the third aspect of the present invention, there is provided a bonding system comprising a measurement unit which measures a state of surfaces of first and second substrates, a processing unit which processes the surfaces of the first and second substrates on the basis of a measurement result of the measurement unit, an operation unit which overlays the first and second substrates processed by the processing unit, and a chamber which accommodates the measurement unit, processing unit, and operation unit and isolates from an outer space, wherein a process for the first and second substrates by the processing unit includes a process of cleaning the surfaces of the first and second substrates.

According to the fourth aspect of the present invention, there is provided a semiconductor substrate manufacturing method comprising steps of forming a porous layer on a substrate, forming a layer to be transferred on the porous layer, bonding the substrate with another substrate by utilizing the bonding system as described above, thereby fabricating a bonded substrate stack, and separating the bonded substrate stack at a portion of the porous layer.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIGS. 1A to 1E are schematic views for schematically explaining an SOI substrate manufacturing method according to a preferred embodiment of the present invention;

FIG. 2 is a view for explaining the operation of a bonding system according to the first preferred embodiment of the present invention;

FIG. 3 is an enlarged view showing a structure in a loader;

FIG. 4 is a schematic view of the structure of an activation unit;

FIGS. 5A and 5B are schematic views of the structure of a bonding unit;

FIG. 6 is a graph showing the numbers of particles on substrate surfaces;

FIG. 7 is a view for explaining the operation of a bonding system according to the second preferred embodiment of the present invention; and

FIG. 8 is a graph showing the numbers of particles on substrate surfaces.

### DETAILED DESCRIPTION OF THE PREFERRED EMBODIMENTS

### Embodiment

The first preferred embodiment of the present invention will be described in detail with reference to the accompanying drawings. Note that the same reference numerals in the respective drawings denote the similar elements.

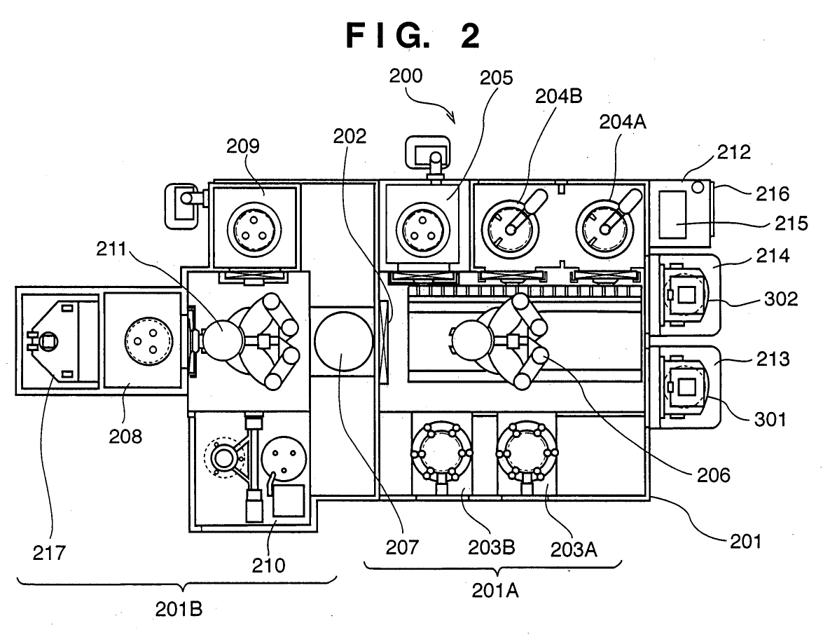

This embodiment shows a bonding system for bonding substrates as an example. FIG. 2 is a conceptual view showing the arrangement of a bonding system 200 according to the first preferred embodiment of the present invention.

As shown in FIG. 2, the bonding system 200 has a chamber 201. The atmosphere outside the chamber 201 does not substantially enter the chamber 201. The chamber 201 has, in it, a cleaning unit 201A which sets (resets) a substrate surface to a predetermined state and a bonding unit 201B which bonds substrates by increasing the bonding strength of the substrates. A central shutter 202 that can be opened/closed is provided at the boundary portion of the cleaning unit 201A and bonding unit 201B.

In the bonding system 200, a filter (not shown; e.g., a particle filter or chemical filter) is arranged in the upper portion of the chamber 201. The atmosphere sealed in the chamber 201 flows down through the filter.

The bonding system 200 further has a moisture controlling unit 217, so that the moisture in the bonding system 200 can be monitored. The moisture controlling unit 217 monitors the moisture in the bonding system 200, and automatically performs humidification if it is less than the regulated value and performs dehumidification if it is larger than the regulated value. Thus, the moisture in the bonding system 200 can be controlled.

Even when substrates are to be transported among respective units in the bonding system 200, unnecessary particles, organic substances, moisture, and the like can be prevented from attaching to the substrates.

The cleaning unit 201A has aligners 203A and 203B which align the substrates, cleaning/drying units 204A and 204B which clean and dry the substrates, a moisture/organic substance/activation reset unit 205 which resets the states of the moisture, organic substance, and activation of the substrates, and a robot 206 which transports the substrates in the cleaning unit 201A.

The aligners 203A and 203B can align the plane orientations and positions of the substrates on the basis of notches or the like formed in the substrates. Thus, even if the position or OF (Orientation Flat) of the substrate differs from one substrate to another, it can be corrected for each substrate.

The cleaning/drying units 204A and 204B remove particles on the surfaces of the substrates by using a chemical solution (e.g., H₂O such as ultra pure water, H₂O₂, H₂SO₄, HF, NH₄OH, HCl, O₃, a surfactant, or the like, or a solution mixture of them) which cleans the substrates. Each of the cleaning/drying units 204A and 204B may use a mechanism which applies ultrasonic vibration, or a mechanism which cleans the substrate while rotating the substrate. The cleaning/drying units 204A and 204B dry the cleaned substrates by N₂ blowing, spin drying, or the like.

The moisture/organic substance/activation reset unit 205 has, e.g., a heating means. The heating means heats the substrate to, e.g., about 100° C. to 500° C., to remove the moisture and organic substances on the substrate surface or contained in the substrate, and sets (resets) the activation state of the substrate surface to a predetermined state (e.g., changes the bonded state of the molecules on the substrate surface so that the bonded molecules on the substrate surface are disconnected). As the heating means, for example, a hot plate, lamp irradiation, or the like can be used. As another means, an evacuating device may be used to expose the substrate to vacuum (for example, the vacuum degree suffices if it is about 10⁻² Torr, or may be at a higher vacuum than that). Alternatively, the evacuating device and the heating means described above may be combined.

The robot 206 has a robot hand which chucks and holds the lower surface of the substrate, and can move on a support table. With this robot hand, the substrate surface (e.g., a surface where a porous layer or the like is to be formed) can be prevented from being contaminated or damaged.

The bonding unit 201B has a transfer stage 207 which transfers a wafer through the central shutter 202, an activation unit 208 which activates the substrate surface, a moisture readjusting unit 209 which adjusts the moisture on the substrate surface within the regulated value range, a bonding unit 210 which bonds substrates, and a robot 211 which transports the substrates within the bonding unit 201B. Schematically, the robot 211 has the same arrangement as that of the robot 206.

The transfer stage 207 is used for temporarily holding the substrate when the substrate is to be transferred from the robot 206 to the robot 211 or vice versa through the central shutter 202.

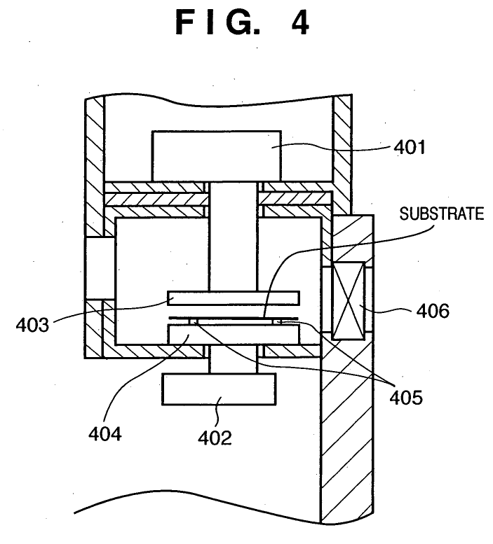

FIG. 4 shows the schematic structure of the activation unit 208. As shown in FIG. 4, the activation unit 208 has an upper power supply 401 and lower power supply 402 arranged above and below the substrate. A gas is supplied to a portion between an upper electrode 403 and lower electrode 404 connected to the distal ends of the upper power supply 401 and lower power supply 402, respectively. A DC voltage or RF voltage is applied between the upper electrode 403 and lower electrode 404 in order to excite a plasma. Ions in the plasma bombard the substrate surface to activate it. Pins 405 are disposed on the lower electrode 404. The substrate is supported through the pins 405. Thus, the substrate can be prevented from being contaminated by direct contact with the lower electrode 404. The activation unit 208 also has a shutter 406 through which the wafer is transported to and from the robot 211. The shutter 406 can prevent the atmosphere in the activation unit 208 from flowing to the outside.

The moisture readjusting unit 209 has a controlling means for controlling the temperature, moisture (humidity), and the like, and maintains the temperature, moisture (humidity), and the like in it at constant values. Thus, the moisture on the surface of the substrate transported into the moisture readjusting unit 209 can be saturated within the regulated value range.

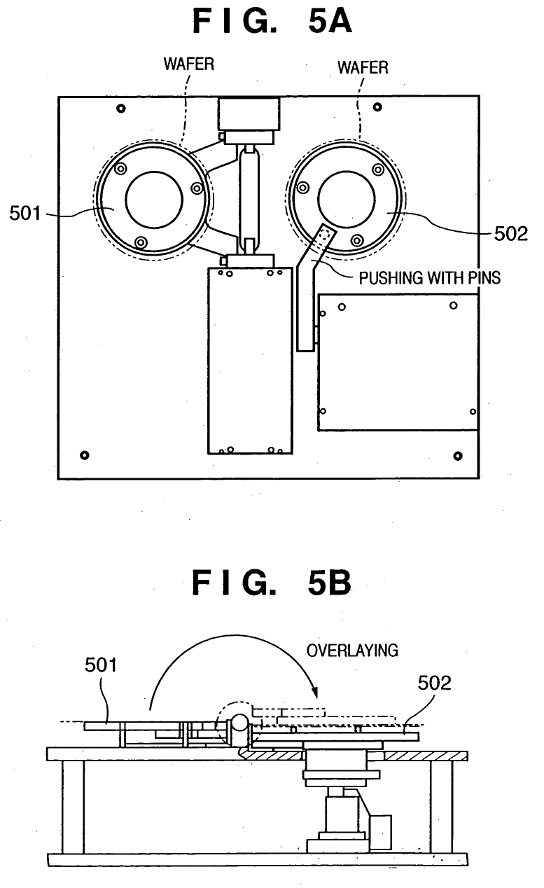

FIGS. 5A and 5B schematically show the structure of the bonding unit 210. FIG. 5A is a plan view of the bonding unit 210 seen from above, and FIG. 5B is a side view of the bonding unit 210. As shown in FIG. 5A, the bonding unit 210 has a first holder 501 which holds the first substrate, and a second holder 502 which holds the second substrate. The first holder 501 is connected to a support, so that the first holder 501 can rotate. As shown in FIG. 5B, when the first holder 501 rotates, the first substrate held on the first holder 501 is overlaid on the second substrate on the second holder 502. Furthermore, when the lower surface of the overlaid substrate stack is pushed with pins or the like, the first and second substrates are bonded to each other entirely.

The bonding system 200 also has a console 212 and loaders 213 and 214 outside the chamber 201.

The console 212 has, in it, a controller 215 for controlling the respective units of the bonding system 200. The controller 215 has, e.g., a CPU, and is provided with a storage medium or the like for storing a control program, data, and the like for the CPU. The console 212 has an operation panel 216 on its one surface. The user can input respective setting conditions from the operation panel 216, so that the user can operate the respective units in the bonding system 200. The controller 215 may read and execute the program codes of the control program stored in its storage medium, so that the bonding system 200 can be operated automatically. Alternatively, the controller 215 may read and execute the program codes of the control program stored in a storage medium which is connected to the controller 215 such that it can communicate with the controller 215.

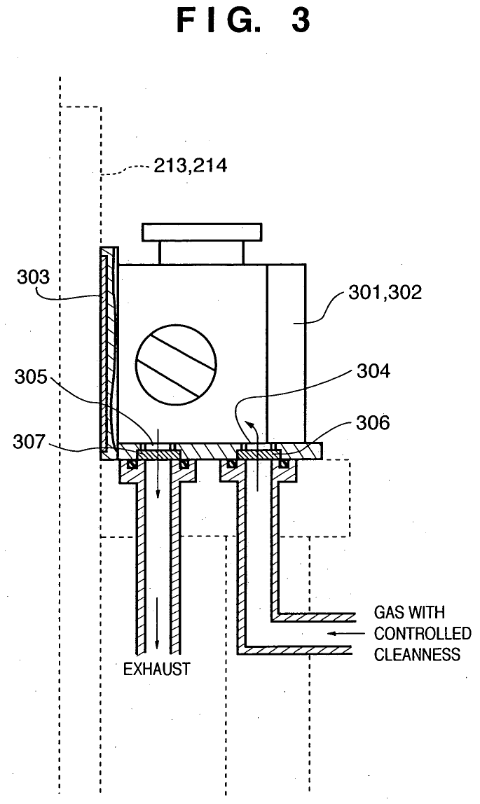

The loaders 213 and 214 are connected to the bonding system 200, and their front surfaces form part of the outer wall of the bonding system 200. FIG. 3 is an enlarged view of a structure in each of the loaders 213 and 214. In FIG. 3, the broken line indicates part of each of the loaders 213 and 214. Sealing containers 301 and 302 in tight contact with the outer wall through seal members 303 are arranged in the loaders 213 and 214, respectively. The sealing containers 301 and 302 have openings that can be opened and closed. When the openings are opened, the sealing containers 301 and 302 and the bonding system 200 share the same space. The sealing containers 301 and 302 also have suction holes 304 and exhaust holes 305. A gas with a controlled cleanness is introduced from the suction holes 304 into the sealing containers 301 and 302 through filters 306 which remove particles, organic substances, and the like. The gas is discharged from the exhaust holes 305 through filters 307 similarly.

According to the mechanism of this embodiment, the atmosphere in the sealing containers 301 and 302 are purged through the filters 306 and 307, so that the outer atmosphere will not accidentally enter the chamber 201. This embodiment is not limited to this. For example, in order that the outer atmosphere will not accidentally enter the chamber 201, the bonding system 200 may have a mechanism for increasing the internal pressure in the bonding system 200, in place of or in addition to the purging mechanism described above.

In particular, the atmospheres in the cleaning/drying units 204A and 204B, moisture/organic substance/activation reset unit 205, activation unit 208, and moisture readjusting unit 209 can undesirably flow into the bonding system 200. Therefore, desirably, these units have shutters individually, and exhaust their atmospheres independently of each other, so that their atmospheres are disconnected from each other.

The operation of the bonding system 200 according to the first preferred embodiment of the present invention will be described with reference to FIG. 2.

First, the first and second substrates as the processing targets, which are sealed in the sealing containers 301 and 302, are set on the corresponding loaders (openers) 213 and 214 from the outside of the bonding system 200. When the first and second substrates are set on the loaders 213 and 214, the gas with the controlled cleanness (e.g., dry nitrogen or the like) is introduced from the suction holes 304 formed in the lower portions of the loaders 213 and 214 into the sealing containers 301 and 302 through the filters 306, as shown in FIG. 3. The gas introduced into the sealing containers 301 and 302 dilutes the atmospheres in the sealing containers 301 and 302. The diluted atmospheres are discharged from the exhaust holes 305 through the filters 307. In this manner, the atmospheres in the sealing containers 301 and 302 are purged by the gas with the controlled cleanness described above.

The atmospheres in the sealing containers 301 and 302 are preferably purged by the gas with the controlled cleanness. The volumes of the sealing containers 301 and 302 are much smaller than the volume in the bonding system 200 (cleaning unit 201A). Hence, even if the openings of the sealing containers 301 and 302 are opened, the atmospheres in the sealing containers 301 and 302, together with the atmosphere controlled in the bonding system 200 (cleaning unit 201A), are pushed out to the outside of the bonding system 200 within a short period of time since the time point at which the interiors of the sealing containers 301 and 302 and the interior of the bonding system 200 (cleaning unit 201A) form one space. Therefore, even when this purging operation is not performed, it will adversely affect the operation of the bonding system 200 at a low possibility.

After that, the sealing containers 301 and 302 come into tight contact with the loaders 213 and 214, the front surfaces of which form part of the outer wall of the bonding system 200, through the seal members 303. The openings of the sealing containers 301 and 302 open, and the interiors of the sealing containers 301 and 302 and the interior of the bonding system 200 (cleaning unit 201A) form one space. The operation of opening part (openings) of the sealing containers 301 and 302, after the sealing containers 301 and 302 come into tight contact with the loaders 213 and 214, can be realized by using a commercially available unit called an opener.

The robot 206 arranged in the cleaning unit 201A extracts the first substrate as the processing target from the sealing container 301 in the loader (opener) 213, and the second substrate as the processing target from the sealing container 302 in the loader (opener) 214.

The robot 206 that has extracted the first and second substrates sets them on the aligners 203A and 203B, respectively. The aligners 203A and 203B align the surface orientations and positions of the substrates on the basis of the notches or the like formed in the substrates. The robot 206 extracts the aligned substrates from the aligners 203A and 203B, and sets them in the cleaning/drying units 204A and 204B. The cleaning/drying units 204A and 204B clean the first and second substrates by using a chemical solution. (e.g., H₂O such as ultra pure water, H₂O₂, H₂SO₄, HF, NH₄OH, HCl, O₃, a surfactant, or the like, or a solution mixture of them) which cleans the first and second substrates, and remove (reset) the particles on the surfaces of the first and second substrates (for about 1 min). The cleaned first and second substrates are dried by N₂ blowing, spin drying, or the like.

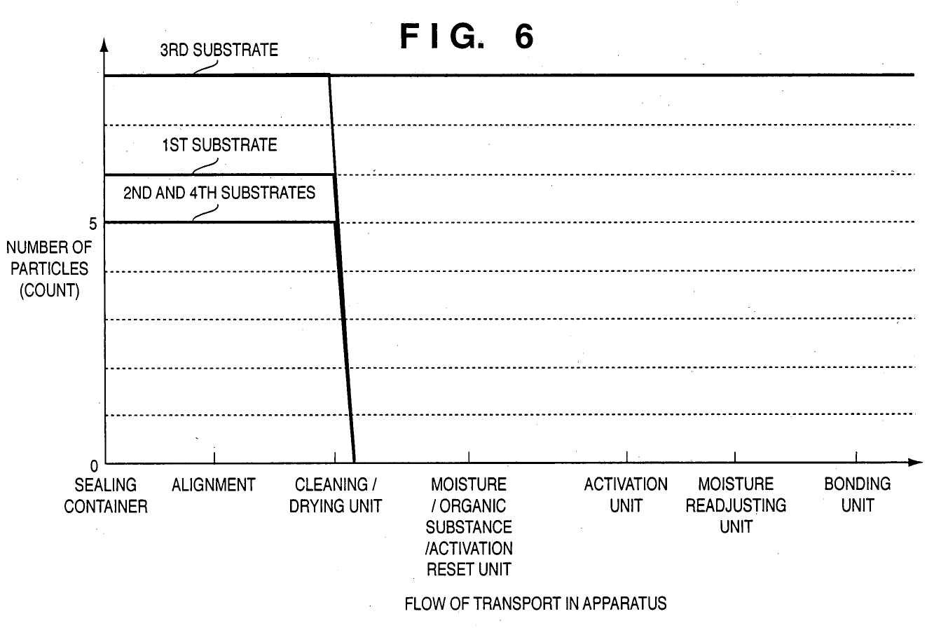

FIG. 6 shows the numbers of particles on the substrate surfaces on the time axis of transport to the respective units in the bonding system 200. As shown in FIG. 6, the particles on each substrate surface are completely removed (reset), after the substrate is loaded in the cleaning/drying units 204A and 204B, during proceeding to the subsequent process (in this embodiment, the moisture/organic substance/activation reset unit 205).

Subsequently, the robot 206 extracts the first or second substrate from which the particles have been removed, and sets it in the moisture/organic substance/activation reset unit 205. In the moisture/organic substance/activation reset unit 205, the moisture and organic substances on the substrate surface are removed by heating the substrate with the heating means and disposing the substrate in the vacuum, or by the combination of the two, and the activation state of the substrate surface is set (reset) to a predetermined state.

The robot 206 then extracts the first or second substrate from the moisture/organic substance/activation reset unit 205, and sets it on the transfer stage 207 after the central shutter 202 is opened. The central shutter 202 is desirably closed as soon as the first or second substrate is set on the transfer stage 207.

The robot 211 extracts the first or second substrate set on the transfer stage 207 and sets it on the activation unit 208. In the activation unit 208, ions in the plasma bombard the substrate surface to activate it (for about 30 sec), so that the surface can be bonded easily. The robot 211 then extracts the first or second substrate from the activation unit 208 and sets it in the moisture readjusting unit 209. In the moisture readjusting unit 209, the substrate is exposed to a predetermined temperature and moisture (humidity), so that the moisture on the surface of the first or second substrate is saturated within the regulated value range (for about 30 sec). The robot 211 then extracts the first or second substrate from the moisture readjusting unit 209 and sets it in the bonding unit 210.

In the bonding unit 210, when the first and second substrates are set on the first and second holders 501 and 502, respectively, the first holder 501 is rotated to overlay the first and second substrates. Furthermore, the lower surface of the overlaid substrate stack is pushed with pins or the like, so that the substrates are bonded entirely, thus forming a bonded substrate stack.

The robot 211 extracts the bonded substrate stack from the bonding unit 210, and transfers it to the robot 206 after the central shutter 202 is opened. The central shutter 202 is desirably closed as soon as the bonded substrate stack is transferred to the robot 206. Subsequently, the robot 206 sets the bonded substrate stack in the sealing container 301 or 302 after the opening of the corresponding sealing container 301 or 302 is opened. The opening of the sealing container 301 or 302 is desirably closed as soon as the bonded substrate stack is transferred to the sealing container 301 or 302. The sealing containers 301 and 302 are extracted from the bonding system 200 as they are sealed completely.

As shown in FIG. 6, after the particles are completely removed (reset) by the cleaning/drying units 204A and 204B, no particles attach to the substrate surface. The interior of the bonding system 200 is a substantially sealed space. The atmosphere in the bonding system 200 flows down through the filter which is formed in its upper portion to remove the particles and organic substances. The moisture in the bonding system 200 is controlled by the moisture controlling unit 217. Therefore, while transporting the substrate in the bonding system 200, not only particles but also any unnecessary organic substance or moisture does not attach to the substrate.

In this manner, according to this embodiment, since the entire bonding system is covered with a chamber almost completely, the outer atmosphere (e.g., a clean room atmosphere) does not enter the bonding system. Also, while transporting the substrate into the bonding system, the atmosphere in the transport container (sealing container) is purged by a clean atmosphere (dry nitrogen or the like) through a filter (which removes particles and organic substances), or the pressure in the bonding system is increased. A predetermined moisture atmosphere is maintained in the bonding system. Therefore, when transporting the substrate among respective units in the bonding system, no unnecessary particles, organic substances, moisture, or the like attaches to the substrate. The atmospheres in the cleaning unit and bonding unit are disconnected by the central shutter. Thus, the atmosphere in one unit does not flow into the other unit.

In the bonding system, the surface state (states of the particles, moisture, organic substance, or the like, and the activation state) of the substrate is reset once. The substrates are bonded after the activation state and moisture on each substrate surface are readjusted to a state optimal for high bonding strength. Therefore, bonded substrate stacks having high bonding strengths can be fabricated without any individual difference.

### Second Embodiment

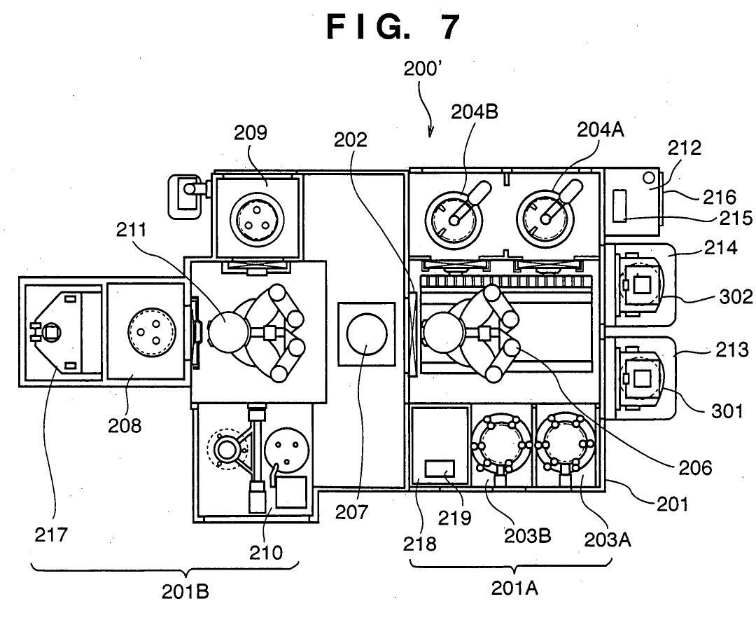

FIG. 7 is a conceptual view showing the arrangement of a bonding system 200′ according to the second preferred embodiment of the present invention. The bonding system 200′ according to this embodiment is obtained by partly changing the arrangement of the bonding system according to the first preferred embodiment of the present invention. More specifically, a cleaning unit 201A has a measurement device 218, which measures the state of the substrate surface, in place of the moisture/organic substance/activation reset unit 205. Except for this, the arrangement of the bonding system 200′ is substantially the same as that of the bonding system according to the first embodiment. Accordingly, a description of portions that are common with the first embodiment will be omitted.

The measurement device 218 can measure the state of the substrate surface, e.g., particles, organic substances, or the like attaching to the substrate surface. Although the measurement device is not particularly limited, for example, an inline particle detection device can be used for measurement of the particles, and the Auger electron spectroscopy (AES), X-ray electron spectroscopy (XPS), Fourier-transform infrared spectroscopy (FT-IR), thermal desorption analysis (TDS), or the like can be used for measurement of the organic substances. The measurement result of such a measurement device 218 can be stored in the storage medium of, e.g., a controller 215. The controller 215 reads and executes the program codes of a predetermined control program on the basis of the measurement result, so that the respective units in the bonding system 200′ can be controlled. The measurement result of the measurement device 218 may be stored in a recording medium that can be loaded in and unloaded from the measurement device 218, or in a storage medium which is connected to the measurement device 218 such that it can communicate with the measurement device 218.

The measurement device 218 further has a determination device 219 which checks whether or not the measurement result is within a predetermined range. Thus, the respective units (cleaning/drying units 204A and 204B in this embodiment) in the bonding system 200′ can be controlled such that they do not perform their processes if the determination device 219 determines that the measurement result is within the predetermined range, and perform their processes if the determination device 219 determines that the measurement result is not within the predetermined range. According to this embodiment, the measurement device 218 includes the determination device 219. However, the present invention is not limited to this. Alternatively, for example, the controller 215 may include the determination device 219.

The cleaning/drying units 204A and 204B are controlled such that, when the determination device 219 determines that the amount of particles or organic substances on the substrate surface measured by the measurement device 218 is larger than a predetermined amount (e.g., the amount of attaching particles per substrate should be 0, and the amount of attaching organic substances per substrate should be 10 pg), the conditions such as the cleaning time and the type of chemical solution are determined on the basis of the measurement result, so that the amount of particles or organic substances on the substrate surface is equal or smaller than the predetermined amount. As the chemical solution for cleaning the substrate, for example, H₂O such as ultra pure water, H₂O₂, H₂SO₄, HF, NH₄OH, HCl, O₃, a surfactant, or the like, or a solution mixture of them can be used. Each of the cleaning/drying units 204A and 204B may use a mechanism which applies ultrasonic vibration, or a mechanism which cleans the substrate while rotating the substrate. To remove the organic substances, O₃ cleaning is preferably employed. Alternatively, the organic substances may be removed by irradiation with ultrasonic rays. The cleaning/drying units 204A and 204B dry the cleaned substrates by N₂ blowing, spin drying, or the like.

The operation of the bonding system 200′ having the above arrangement will be described.

First, the first and second substrates as the processing targets, which are sealed in sealing containers 301 and 302, are set on corresponding loaders (openers) 213 and 214 from the outside of the bonding system 200′. When the first and second substrates are set on the loaders 213 and 214, a gas with a controlled cleanness (e.g., dry nitrogen or the like) is introduced from suction holes 304 formed in the lower portions of the loaders 213 and 214 into the sealing containers 301 and 302 through filters 306, as shown in FIG. 3. The gas introduced into the sealing containers 301 and 302 dilutes the atmospheres in the sealing containers 301 and 302. The diluted atmospheres are discharged from exhaust holes 305 through filters 307. In this manner, the atmospheres in the sealing containers 301 and 302 are purged by the gas with the controlled cleanness described above.

The atmospheres in the sealing containers 301 and 302 are preferably purged by the gas with the controlled cleanness. The volumes of the sealing containers 301 and 302 are much smaller than the volume in the bonding system 200′ (cleaning unit 201A). Hence, even if the openings of the sealing containers 301 and 302 are opened, the atmospheres in the sealing containers 301 and 302, together with the atmosphere controlled in the bonding system 200′ (cleaning unit 201A), are pushed out to the outside of the bonding system 200′ within a short period of time since the time point at which the interiors of the sealing containers 301 and 302 and the interior of the bonding system 200′ (cleaning unit 201A) form one space. Therefore, even when this purging operation is not performed, it will adversely affect the operation of the bonding system 200′ at a low possibility.

After that, the sealing containers 301 and 302 come into tight contact with the loaders 213 and 214, the front surfaces of which form part of the outer wall of the bonding system 200′, through seal members. The openings of the sealing containers 301 and 302 open, and the interiors of the sealing containers 301 and 302 and the interior of the bonding system 200′ (cleaning unit 201A) form one space. The operation of opening part (openings) of the sealing containers 301 and.302, after the sealing containers 301 and 302 come into tight contact with the loaders 213 and 214, can be realized by using a commercially available unit called an opener.

A robot 206 arranged in the cleaning unit 201A extracts the first substrate as the processing target from the sealing container 301 in the loader (opener) 213, and the second substrate as the processing target from the sealing container 302 in the loader (opener) 214.

The robot 206 that has extracted the first and second substrates sets them on the measurement device 218. The measurement device 218 measures the particles or organic substances attaching to the substrate surface. Then, the determination device 219 checks whether or not the measurement result obtained with the measurement device 218 is within a predetermined range. After that, the cleaning/drying units 204A and 204B in the bonding system 200′ do not perform their processes if the determination device 219 determines that the measurement result of the measurement device 218 is within the predetermined range, and perform their processes if the determination device 219 determines that the measurement result of the measurement device 218 is not within the predetermined range.

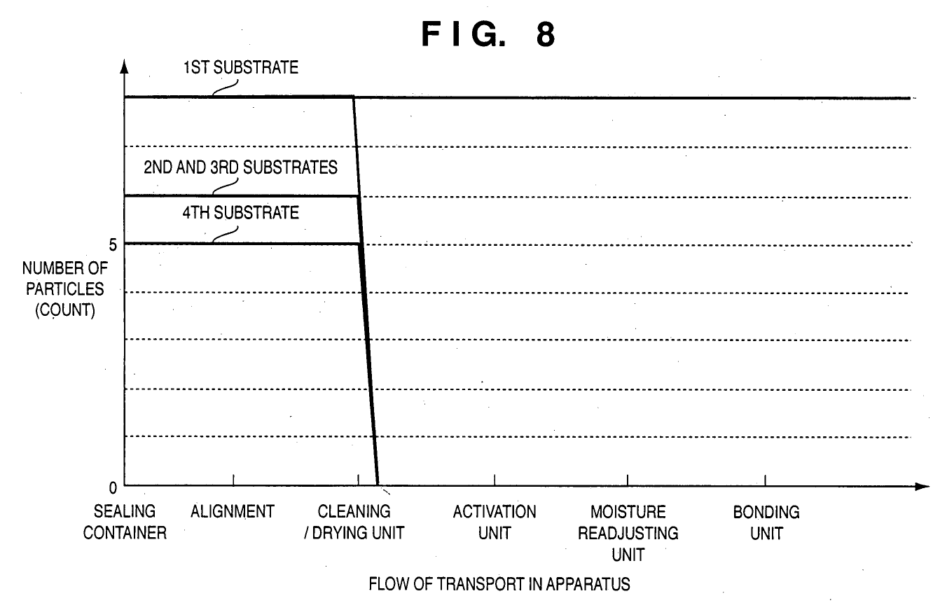

The robot 206 then extracts the first and second substrates from the measurement device 218 and sets them on aligners 203A and 203B, respectively. The aligners 203A and 203B align the surface orientations and positions of the substrates on the basis of notches or the like formed in the substrates. The robot 206 extracts the aligned substrates from the aligners 203A and 203B, and sets them in the cleaning/drying units 204A and 204B. If the determination device 219 determines that the measurement result of the measurement device 218 is not within the predetermined range, the cleaning/drying units 204A and 204B clean the first and second substrates by using a chemical solution (e.g., H₂O such as ultra pure water, H₂O₂, H₂SO₄, HF, NH₄OH, HCl, O₃, a surfactant, or the like, or a solution mixture of them) which cleans the first and second substrates, and remove the particles or organic substances on the surfaces of the first and second substrates (for about 1 min). The cleaned first and second substrates are dried by N₂ blowing, spin drying, or the like. FIG. 8 shows the numbers of particles on the substrate surfaces on the time axis of transport to the respective units in the bonding system 200′. As shown in FIG. 8, the particles on each substrate surface are completely removed, after the substrates are loaded in the cleaning/drying units 204A and 204B, during proceeding to the subsequent process (in this embodiment, an activation unit 208).

Subsequently, the robot 206 extracts the first or second substrate from which the particles have been removed, and sets it on a transfer stage 207 after a central shutter 202 is opened. The central shutter 202 is desirably closed as soon as the first or second substrate is set on the transfer stage 207.

A robot 211 extracts the first or second substrate set on the transfer stage 207 and sets it on the activation unit 208. In the activation unit 208, ions in the plasma bombard the substrate surface to activate it (for about 30 sec), so that the surface can be bonded easily. The robot 211 then extracts the first or second substrate from the activation unit 208 and sets it in a moisture readjusting unit 209. In the moisture readjusting unit 209, the substrate is exposed to a predetermined temperature and moisture (humidity), so that the moisture on the surface of the first or second substrate is saturated within a regulated value range (for about 30 sec). The robot 211 then extracts the first or second substrate from the moisture readjusting unit 209 and sets it in a bonding unit 210.

In the bonding unit 210, when the first and second substrates are set on first and second holders 501 and 502, respectively, the first holder 501 is rotated to overlay the first and second substrates. Furthermore, the lower surface of the overlaid substrate stack is pushed with pins or the like, so that the substrates are bonded entirely, thus forming a bonded substrate stack.

The robot 211 extracts the bonded substrate stack from the bonding unit 210, and transfers it to the robot 206 after the central shutter 202 is opened. The central shutter 202 is desirably closed as soon as the bonded substrate stack is transferred to the robot 206.

Subsequently, the robot 206 sets the bonded substrate stack in the sealing container 301 or 302 after the opening of the corresponding sealing container 301 or 302 is opened. The opening of the sealing container 301 or 302 is desirably closed as soon as the bonded substrate stack is transferred to the sealing container 301 or 302. The sealing containers 301 and 302 are extracted from the bonding system 200′ as they are sealed completely.

As shown in FIG. 8, after the particles are completely removed by the cleaning/drying units 204A and 204B, no particles attach to the substrate surface. The interior of the bonding system 200′ is a substantially sealed space. The atmosphere in the bonding system 200′ flows down through a filter which is formed in its upper portion to remove the particles and organic substances. The moisture in the bonding system 200′ is controlled by a moisture controlling unit 217. Therefore, while transporting the substrate in the bonding system 200′, not only particles but also any unnecessary organic substance or moisture does not attach to the substrate.

In this manner, according to this embodiment, since the entire bonding system is covered by a chamber almost completely, the outer atmosphere (e.g., a clean room atmosphere) does not enter the bonding system. Also, while transporting the substrate into the bonding system, the atmosphere in the transport container (sealing container) is purged by a clean atmosphere (dry nitrogen or the like) through a filter (which removes particles and organic substances), or the pressure in the bonding system is increased. A predetermined moisture atmosphere is maintained in the bonding system. Therefore, while transporting the substrate among the units in the bonding system, no unnecessary particles, organic substances, moisture, or the like attaches to the substrate. The atmospheres in the cleaning unit and bonding unit are disconnected by the central shutter. Thus, the atmosphere in one unit does not flow into the other unit.

In the bonding system, the surface state of the substrate is measured. The surface process (removal of the particles and organic substances) is performed when it is determined that the measurement result is not within the predetermined range. Only substrates that need process can accordingly be processed, thus improving the yield. The substrates are bonded after the activation state and moisture on each substrate surface are readjusted to a state optimal for high bonding strength. Therefore, bonded substrate stacks having high bonding strengths can be fabricated without any individual difference.

<Application of Substrate Transport Apparatus>

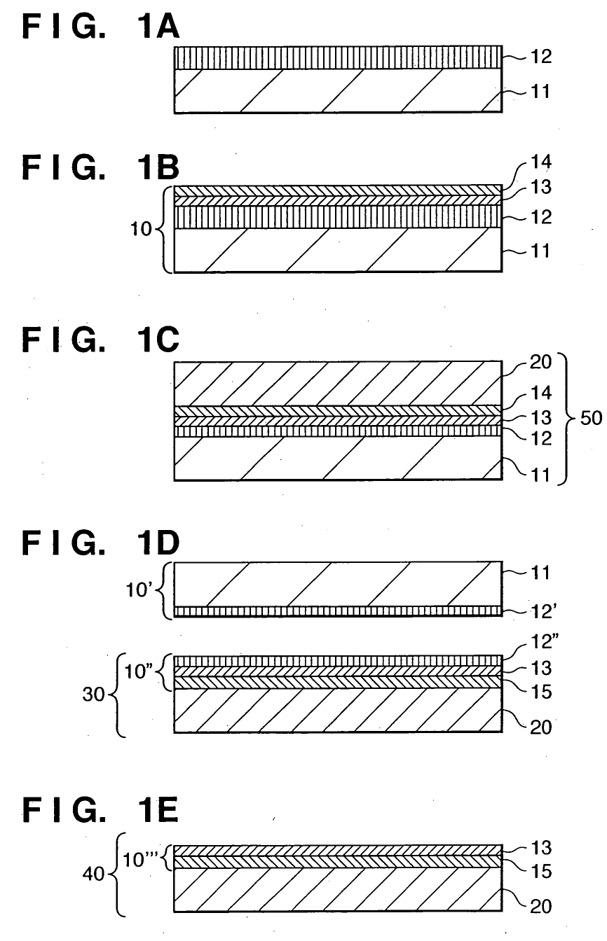

An example in which the bonding system according the first or second preferred embodiment of the present invention is applied to a substrate manufacturing method will be exemplified by an SOI substrate manufacturing method. FIGS. 1A to 1E are schematic views for schematically explaining the SOI substrate manufacturing method according to a preferred embodiment of the present invention.

In the process shown in FIG. 1A, a single crystal Si substrate 11 is prepared, and a porous Si layer 12 is formed on the surface of the single crystal Si substrate 11 by an anode formation process or the like.

In the process shown in FIG. 1B, a nonporous single crystal Si layer 13 is formed on the porous Si layer 12 by epitaxial growth. After that, the surface of the nonporous single crystal Si layer 13 is oxidized to form an insulating layer (SiO₂ layer) 14. Thus, a first substrate 10 is formed. Alternatively, the porous Si layer 12 may be formed by a method (ion implantation) of implanting ions of hydrogen, helium, an inert gas, or the like into the single crystal Si substrate 11. A porous Si layer formed by this method has a large number of microcavities, and is called a microcavity layer as well.

In the process shown in FIG. 1C, a second substrate 20 made of single crystal Si is prepared by using the bonding system according to the first or second preferred embodiment of the present invention. The first substrate 10 and second substrate 20 are brought into tight contact with each other in room temperature such that the second substrate 20 and the insulating layer 14 face each other, thus forming a bonded substrate stack 50. When the bonding system according to the first or second preferred embodiment of the present invention is used, the bonding strength of the bonded substrate stack 50 can be increased.

The insulating layer 14 may be formed on the nonporous single crystal Si layer 13, as described above, or on the second substrate 20, or between the nonporous single crystal Si layer 13 and second substrate 20. It suffices as far as the state shown in FIG. 1C is obtained when the first and second substrates are brought into tight contact with each other. When the insulating layer 14 is formed on the nonporous single crystal Si layer 13 which forms a prospective active layer, as described above, the bonding interface of the first and second substrates 10 and 20 can be set away from the active layer. As a result, a higher-quality SOI substrate can be obtained.

In the process shown in FIG. 1D, the porous Si layer 12 is subjected to separation to separate the bonded substrate stack 50 into a new first substrate 10′ and new second substrate 30. As the separation method, a method of inserting a wedge in a portion near the porous Si layer 12, a method of blowing a high-pressure fluid to a portion near the porous Si layer 12, or the like is available.

After that, in the process shown in FIG. 1E, etching with high selectivity is performed with a porous layer 12″ and the single crystal Si layer 13, so that a porous layer 12′ is removed without substantially reducing the thickness of the nonporous single crystal Si layer 13, thus forming an SOI substrate 40. With this method, the single crystal Si layer 13 and insulating layer 14 as the layers to be transferred can be transferred to the second substrate 30. When the second substrate 30 is annealed in a hydrogen atmosphere, an SOI substrate having a very flat surface can be obtained. Furthermore, when the SOI substrate 40 is annealed in a hydrogen atmosphere, an SOI substrate having a very flat surface can be obtained.

In this manner, when the bonding system according to a preferred embodiment of the present invention is applied to the substrate manufacturing method, bonded substrate stacks having high bonding strengths can be fabricated without any individual difference.

As has been described above, the quality of the bonded quality can be improved.

As many apparently widely different embodiments of the present invention can be made without departing from the spirit and scope thereof, it is to be understood that the invention is not limited to the specific embodiments thereof except as defined in the appended claims.

What is claimed is:

1. A bonding system comprising:
a processing unit which processes surfaces of first and second substrates;
an operation unit which overlays the first and second substrates processed by said processing unit; and
a chamber which accommodates and isolates from an outer space said processing unit and operation unit,
wherein a process for the first and second substrates by said processing unit includes a process of cleaning and/or activating the surfaces of the first and second substrates.

2. The system according to claim 1, further comprising a filter, wherein an interior of said chamber is cleaned by said filter.

3. The system according to claim 1, further comprising a loader connected to said chamber, said loader including a mechanism which purges an atmosphere in said chamber.

4. The system according to claim 1, further comprising a mechanism which increases a pressure in said chamber to be higher than that outside said chamber.

5. The system according to claim 1, wherein the process for the first and second substrates by said processing unit includes a process of removing a moisture on the surfaces of the first and second substrates to a predetermined level.

6. The system according to claim 1, wherein the process for the first and second substrates by said processing unit includes a process of removing a moisture on the surfaces of the first and second substrates to a predetermined level and thereafter setting the moisture on the surfaces to a predetermined level so that a bonding strength of the first and second substrates increases.

7. The system according to claim 1, wherein said processing unit comprises a mechanism which removes a particle on the surfaces of the first and second substrates.

8. The system according to claim 1, wherein said processing unit comprises a mechanism which removes an organic substance on the surfaces of the first and second substrates.

9. The system according to claim 1, wherein said processing unit comprises a mechanism which sets an activation state of the surfaces of the first and second substrate to a predetermined state.

10. The system according to claim 9, wherein said processing unit comprises a mechanism which activates the surfaces of the first and second substrates so that a bonding strength of the first and second substrates increases.

11. A bonding system comprising:
an operation unit which overlays first and second substrates;
a chamber which accommodates said operation unit and isolates said operation unit from an outer space; and
a humidity maintaining unit which maintains a humidity in said chamber to a substantially constant level.

12. A bonding system comprising:
a measurement unit which measures a state of surfaces of first and second substrates;
a processing unit which processes the surfaces of the first and second substrates on the basis of a measurement result of said measurement unit;
an operation unit which overlays the first and second substrates processed by said processing unit; and
a chamber which accommodates said measurement unit, processing unit, and operation unit and isolates from an outer space,
wherein a process for the first and second substrates by said processing unit includes a process of cleaning the surfaces of the first and second substrates.

13. The system according to claim 12, further comprising a determination unit which checks whether or not the measurement result of said measurement unit is within a predetermined range, wherein the process by said processing unit is performed when said determination unit determines that the measurement result is not within the predetermined range.

14. The system according to claim 12, further comprising a filter, wherein an interior of said chamber is cleaned by said filter.

15. The system according to claim 12, further comprising a loader connected to said chamber, said loader including a mechanism which purges an atmosphere in said chamber.

16. The system according to claim 12, further comprising a mechanism which increases a pressure in said chamber to be higher than that outside said chamber.

17. The system according to claim 12, wherein said processing unit comprises a mechanism which removes a particle on the surfaces of the first and second substrates.

18. The system according to claim 12, wherein said processing unit comprises a mechanism which removes an organic substance on the surfaces of the first and second substrates.

19. The system according to claim 12, wherein said processing unit comprises a mechanism which activates the surfaces of the first and second substrates so that a bonding strength of the first and second substrates increases.

20. The system according to claim 12, wherein the process for the first and second substrates by said processing unit includes a process of setting a moisture on the surfaces of the first and second substrates to a predetermined level so that a bonding strength of the first and second substrates increases.

21. The system according to claim 12, further comprising a humidity maintaining unit which maintains a humidity in said chamber to a substantially constant level.

22. A semiconductor substrate manufacturing method comprising steps of:
forming a porous layer on a substrate;
forming a layer to be transferred on the porous layer;
bonding the substrate with another substrate by utilizing the bonding system according to claim 1, thereby fabricating a bonded substrate stack; and
separating the bonded substrate stack at a portion of the porous layer.
